(19) United States
(12) Patent Application Publication
(10) Pub. No.: US 2020/0326375 A1
(43) Pub. Date: Oct. 15, 2020

(54) Determining Operational Health of a Top Drive

(71) Applicant: Schlumberger Technology Corporation, Sugar land, TX (US)

(72) Inventors: Alejandro Camacho Cardenas, Houston, TX (US); Inaki Jean Pierre Olazabal, Houston, TX (US)

(21) Appl. No.: 16/382,788

(22) Filed: Apr. 12, 2019

(51) Int. Cl. G01R 31/34; E21B 3/02; E21B 44/00; E21B 47/00; G01L 5/00

(52) U.S. Cl. CPC G01R 31/343; E21B 3/02; G01L 5/0042; E21B 47/00; E21B 44/00

(57) ABSTRACT

Methods and systems for determining operational health of a top drive. A method may include commencing operation of a processing device to determine operational health of a top drive for rotating a drill string at a wellsite. The processing device may then output a first control command to a first motor of the top drive to cause the first motor to perform a rotational operation, output a second control command to a second motor of the top drive to cause the second motor to impart a load to the first motor, receive a sensor measurement indicative of an operational parameter of the top drive, and determine operational health of the top drive based on the sensor measurement.

### BACKGROUND OF THE DISCLOSURE

Wells are generally drilled into the ground or ocean bed to recover natural deposits of oil, gas, and other materials that are trapped in subterranean formations. Well construction operations (e.g., drilling operations) may be performed at a wellsite by a drilling system (e.g., drilling rig) having various automated surface and subterranean equipment operating in a coordinated manner. For example, a drive mechanism, such as a top drive located at a wellsite surface, can be utilized to rotate and advance a drill string into a subterranean formation to drill a wellbore. The drill string may include a plurality of drill pipes coupled together and terminating with a drill bit. Length of the drill string may be increased by adding additional drill pipes while depth of the wellbore increases. Drilling fluid may be pumped from the wellsite surface down through the drill string to the drill bit. The drilling fluid lubricates and cools the drill bit, and carries drill cuttings from the wellbore back to the wellsite surface. The drilling fluid returning to the surface may then be cleaned and again pumped through the drill string. The equipment of the drilling system may be grouped into various subsystems, wherein each subsystem performs a different operation controlled by a corresponding local and/or a remotely located controller.

The wellsite equipment is typically monitored and controlled from a control center located at the wellsite surface. A typical control center houses a control station operable to receive sensor measurements from various sensors associated with the wellsite equipment and permit monitoring of the wellsite equipment by the wellsite control station and/or by human wellsite operators. The wellsite equipment may then be automatically controlled by the wellsite control station or manually by the wellsite operator based on the sensor measurements.

Determining operational health of sophisticated wellsite equipment, such as a top drive, based on sensor measurements taken during regular equipment activities can be challenging, especially when such equipment comprises multiple interconnected devices working together and performing a wide array of functions. Equipment complexity increases the difficulty of discriminating between inherent variability of operating functions and variability created by deteriorating operational health. A top drive performs several different activities, comprising varying loads, speeds, and operational sequences, thereby causing inconsistent sensor measurements based on which operational health can be difficult to determine.

### SUMMARY OF THE DISCLOSURE

This summary is provided to introduce a selection of concepts that are further described below in the detailed description. This summary is not intended to identify indispensable features of the claimed subject matter, nor is it intended for use as an aid in limiting the scope of the claimed subject matter.

The present disclosure introduces an apparatus including a system for monitoring operational health of a top drive operable to rotate a drill string at a wellsite. The system includes a sensor, a loading device, and a processing device. The sensor is operatively connected with and/or disposed in association with the top drive and facilitates determination of a sensor measurement of an operational parameter of the top drive. The loading device is detachably connected to a drive shaft of the top drive and imparts a load to a motor of the top drive. The processing device includes a processor and a memory storing computer program code. The processing device is communicatively connected with the sensor and the loading device, outputs a first control command to the motor to cause the motor to perform a rotational operation, outputs a second control command to the loading device to cause the loading device to impart a load to the motor, receives the sensor measurement, and determines operational health of the top drive based on the sensor measurement.

The present disclosure also introduces a method including commencing operation of a processing device to determine operational health of a top drive for rotating a drill string at a wellsite. The processing device outputs a first control command to a motor of the top drive to cause the motor to perform a rotational operation, outputs a second control command to a loading device coupled to a drive shaft of the top drive to cause the loading device to impart a load to the motor, receives a sensor measurement indicative of an operational parameter of the top drive, and determines operational health of the top drive based on the sensor measurement.

The present disclosure also introduces a method including commencing operation of a processing device to determine operational health of a top drive for rotating a drill string at a wellsite. The processing device outputs a first control command to a first motor of the top drive to cause the first motor to perform a rotational operation, outputs a second control command to a second motor of the top drive to cause the second motor to impart a load to the first motor, receives a sensor measurement indicative of an operational parameter of the top drive, and determines operational health of the top drive based on the sensor measurement.

These and additional aspects of the present disclosure are set forth in the description that follows, and/or may be learned by a person having ordinary skill in the art by reading the material herein and/or practicing the principles described herein. At least some aspects of the present disclosure may be achieved via means recited in the attached claims.

### BRIEF DESCRIPTION OF THE DRAWINGS

The present disclosure is understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of at least a portion of an example implementation of apparatus according to one or more aspects of the present disclosure.

FIG. 2 is a schematic view of at least a portion of an example implementation of apparatus according to one or more aspects of the present disclosure.

FIG. 3 is a schematic view of at least a portion of an example implementation of apparatus according to one or more aspects of the present disclosure.

FIG. 4 is a schematic view of at least a portion of an example implementation of apparatus according to one or more aspects of the present disclosure.

FIGS. 5 and 6 are graphs related to one or more aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for simplicity and clarity, and does not in itself dictate a relationship between the various embodiments and/or configurations discussed.

Systems and methods (e.g., processes, operations) according to one or more aspects of the present disclosure may be utilized or otherwise implemented in association with an automated well construction system (e.g., a drilling rig) at an oil and gas wellsite, such as for constructing a wellbore to obtain hydrocarbons (e.g., oil and/or gas) from a subterranean formation. However, one or more aspects of the present disclosure may be utilized or otherwise implemented in association with other automated systems in the oil and gas industry and other industries. For example, one or more aspects of the present disclosure may be implemented in association with wellsite systems for performing fracturing, cementing, acidizing, chemical injecting, and/or water jet cutting operations, among other examples. One or more aspects of the present disclosure may also be implemented in association with mining sites, building construction sites, and/or other work sites where automated machines or equipment are utilized.

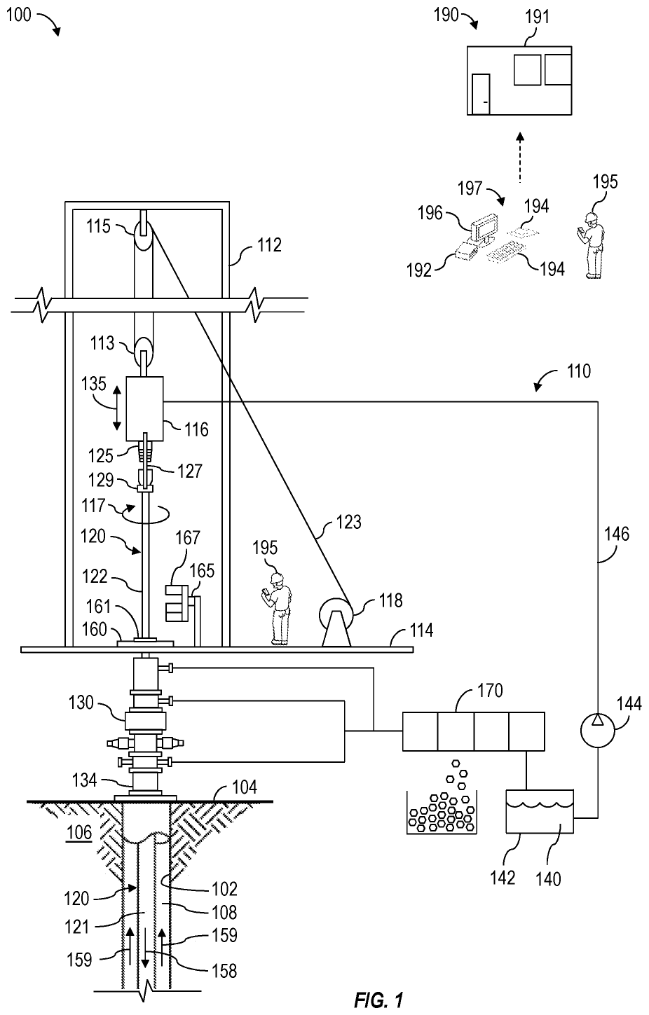

FIG. 1 is a schematic view of at least a portion of an example implementation of a well construction system 100 according to one or more aspects of the present disclosure. The well construction system 100 represents an example environment in which one or more aspects of the present disclosure described below may be implemented. The well construction system 100 may be or comprise a drilling rig and associated wellsite equipment. Although the well construction system 100 is depicted as an onshore implementation, the aspects described below are also applicable to offshore implementations.

The well construction system 100 is depicted in relation to a wellbore 102 formed by rotary and/or directional drilling from a wellsite surface 104 and extending into a subterranean formation 106. The well construction system 100 includes surface equipment 110 located at the wellsite surface 104 and a drill string 120 suspended within the wellbore 102. The surface equipment 110 may include a mast, a derrick, and/or another support structure 112 disposed over a rig floor 114. The drill string 120 may be suspended within the wellbore 102 from the support structure 112. The support structure 112 and the rig floor 114 are collectively supported over the wellbore 102 by legs and/or other support structures (not shown).

The drill string 120 may comprise a bottom-hole assembly (BHA) (not shown) and means 122 for conveying the BHA within the wellbore 102. The conveyance means 122 may comprise a plurality of individual tubulars, such as drill pipe, drill collars, heavy-weight drill pipe (HWDP), wired drill pipe (WDP), tough logging condition (TLC) pipe, and/or other means for conveying the BHA within the wellbore 102. A downhole end of the BHA may include or be coupled to a drill bit (not shown). Rotation of the drill bit and the weight of the drill string 120 collectively operate to form the wellbore 102.

The support structure 112 may support a driver, such as a top drive 116, operable to connect (perhaps indirectly) with an upper end of the drill string 120, and to impart rotary motion 117 and vertical motion 135 to the drill string 120, including the drill bit. However, another driver, such as a kelly (not shown) and a rotary table 160, may be utilized in addition to or instead of the top drive 116 to impart the rotary motion 117 to the drill string 120. The top drive 116 and the connected drill string 120 may be suspended from the support structure 112 via a hoisting system or equipment, which may include a traveling block 113, a crown block 115, and a draw works 118 storing a support cable or line 123. The crown block 115 may be connected to or otherwise supported by the support structure 112, and the traveling block 113 may be coupled with the top drive 116. The draw works 118 may be mounted on or otherwise supported by the rig floor 114. The crown block 115 and traveling block 113 comprise pulleys or sheaves around which the support line 123 is reeved to operatively connect the crown block 115, the traveling block 113, and the draw works 118 (and perhaps an anchor). The draw works 118 may thus selectively impart tension to the support line 123 to lift and lower the top drive 116, resulting in the vertical motion 135. The draw works 118 may comprise a drum, a base, and a prime mover (e.g., an engine or motor) (not shown) operable to drive the drum to rotate and reel in the support line 123, causing the traveling block 113 and the top drive 116 to move upward. The draw works 118 may be operable to reel out the support line 123 via a controlled rotation of the drum, causing the traveling block 113 and the top drive 116 to move downward.

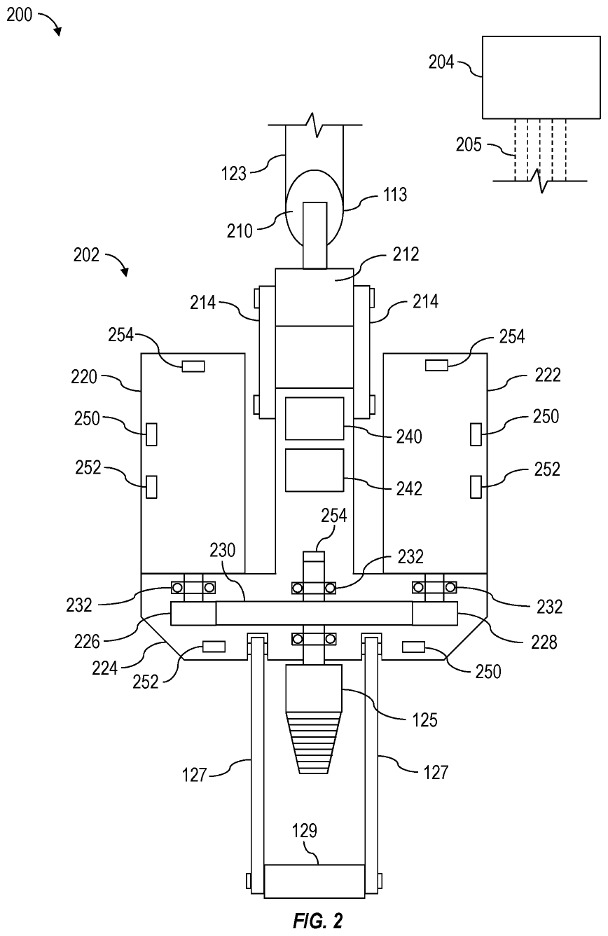

The top drive 116 may comprise a grabber, a swivel (neither shown), elevator links 127 terminating with an elevator 129, and a drive shaft 125 operatively connected with a prime mover (e.g., a rotary actuator 220, 222 shown in FIG. 2), such as via a gear box or transmission (e.g., gear box 224 shown in FIG. 2). The drive shaft 125 may be selectively coupled with the upper end of the drill string 120 and the prime mover may be selectively operated to rotate the drive shaft 125 and the drill string 120 coupled with the drive shaft 125. Hence, during drilling operations, the top drive 116, in conjunction with operation of the draw works 118, may advance the drill string 120 into the formation 106 to form the wellbore 102. The elevator links 127 and the elevator 129 of the top drive 116 may handle tubulars (e.g., drill pipes, drill collars, casing joints, etc.) that are not mechanically coupled to the drive shaft 125. For example, when the drill string 120 is being tripped into or out of the wellbore 102, the elevator 129 may grasp the tubulars of the drill string 120 such that the tubulars may be raised and/or lowered via the hoisting equipment mechanically coupled to the top drive 116. The top drive 116 may have a guide system (not shown), such as rollers that track up and down a guide rail on the support structure 112. The guide system may aid in keeping the top drive 116 aligned with the wellbore 102, and in preventing the top drive 116 from rotating during drilling by transferring reactive torque to the support structure 112.

The well construction system 100 may further include a drilling fluid circulation system or equipment operable to circulate fluids between the surface equipment 110 and the drill bit during drilling and other operations. For example, the drilling fluid circulation system may be operable to inject a drilling fluid from the wellsite surface 104 into the wellbore 102 via an internal fluid passage 121 extending longitudinally through the drill string 120. The drilling fluid circulation system may comprise a pit, a tank, and/or other fluid container 142 holding the drilling fluid (i.e., mud) 140, and a pump 144 operable to move the drilling fluid 140 from the container 142 into the fluid passage 121 of the drill string 120 via a fluid conduit 146 extending from the pump 144 to the top drive 116 and an internal passage extending through the top drive 116.

During drilling operations, the drilling fluid may continue to flow downhole through the internal passage 121 of the drill string 120, as indicated by directional arrow 158. The drilling fluid may exit the BHA via ports in the drill bit and then circulate uphole through an annular space 108 (“annulus”) of the wellbore 102 defined between an exterior of the drill string 120 and the sidewall of the wellbore 102, such flow being indicated by directional arrows 159. In this manner, the drilling fluid lubricates the drill bit and carries formation cuttings uphole to the wellsite surface 104.

The well construction system 100 may further include fluid control equipment 130 for maintaining well pressure control and for controlling fluid being discharged from the wellbore 102. The fluid control equipment 130 may be mounted on top of a wellhead 134. The returning drilling fluid may exit the annulus 108 via one or more valves of the fluid control equipment 130, such as a bell nipple, an RCD, and/or a ported adapter (e.g., a spool, cross adapter, a wing valve, etc.) located below one or more portions of a BOP stack. The returning drilling fluid may then pass through drilling fluid reconditioning equipment 170 to be cleaned and reconditioned before returning to the fluid container 142.

An iron roughneck 165 may be positioned on the rig floor 114. The iron roughneck 165 may comprise a torqueing portion 167, such as may include a spinner and a torque wrench comprising a lower tong and an upper tong. The torqueing portion 167 of the iron roughneck 165 may be moveable toward and at least partially around the drill string 120, such as may permit the iron roughneck 165 to make up and break out connections of the drill string 120. The torqueing portion 167 may also be moveable away from the drill string 120, such as may permit the iron roughneck 165 to move clear of the drill string 120 during drilling operations. The spinner of the iron roughneck 165 may be utilized to apply low torque to make up and break out threaded connections between tubulars of the drill string 120, and the torque wrench may be utilized to apply a higher torque to tighten and loosen the threaded connections.

A set of slips 161 may be located on the rig floor 114, such as may accommodate therethrough the drill string 120 during tubular make up and break out operations, tubular running operations, and the drilling operations. The slips 161 may be in an open position during running and drilling operations to permit advancement of the drill string 120, and in a closed position to clamp the upper end (e.g., uppermost tubular) of the drill string 120 to thereby suspend and prevent advancement of the drill string 120 within the wellbore 102, such as during the make up and break out operations.

The surface equipment 110 of the well construction system 100 may also comprise a control center 190 from which various portions of the well construction system 100, such as the top drive 116, the hoisting system, the tubular handling system, the drilling fluid circulation system, the well control system, the BHA, among other examples, may be monitored and controlled. The control center 190 may be located on the rig floor 114 or another location of the well construction system 100, such as the wellsite surface 104. The control center 190 may comprise a facility 191 (e.g., a room, a cabin, a trailer, etc.) containing a control workstation 197, which may be operated by a human wellsite operator 195 to monitor and control various wellsite equipment or portions of the well construction system 100. The control workstation 197 may comprise or be communicatively connected with a processing device 192 (e.g., a controller, a computer, etc.), such as may be operable to receive, process, and output information to monitor operations of and provide control to one or more portions of the well construction system 100. For example, the processing device 192 may be communicatively connected with the various surface and downhole equipment described herein, and may be operable to receive signals from and transmit signals to such equipment to perform various operations described herein. The processing device 192 may store executable program code, instructions, and/or operational parameters or setpoints, including for implementing one or more aspects of methods and operations described herein. The processing device 192 may be located within and/or outside of the facility 191.

The control workstation 197 may be operable for entering or otherwise communicating control commands to the processing device 192 by the wellsite operator 195, and for displaying or otherwise communicating information from the processing device 192 to the wellsite operator 195. The control workstation 197 may comprise a plurality of human-machine interface (HMI) devices, including one or more input devices 194 (e.g., a keyboard, a mouse, a joystick, a touchscreen, etc.) and one or more output devices 196 (e.g., a video monitor, a touchscreen, a printer, audio speakers, etc.). Communication between the processing device 192, the input and output devices 194, 196, and the various wellsite equipment may be via wired and/or wireless communication means. However, for clarity and ease of understanding, such communication means are not depicted, and a person having ordinary skill in the art will appreciate that such communication means are within the scope of the present disclosure.

Well construction systems within the scope of the present disclosure may include more or fewer components than as described above and depicted in FIG. 1. Additionally, various equipment and/or subsystems of the well construction system 100 shown in FIG. 1 may include more or fewer components than as described above and depicted in FIG. 1. For example, various engines, motors, hydraulics, actuators, valves, and/or other components not explicitly described herein may be included in the well construction system 100, and are within the scope of the present disclosure.

The present disclosure is further directed to various implementations of systems and/or methods for monitoring operational health (e.g., condition, level or progression of wear, degradation, and/or deterioration, etc.) of a top drive for rotating a drill string at a wellsite. Such systems and/or methods may comprise systems and/or methods for controlling operations of the top drive and monitoring operational parameters of the top during the controlled operations. The systems and/or methods for monitoring the operational health of the top drive may then determine the operational health of the top drive based on the operational parameters that were generated during the controlled operations.

An operational health monitoring system according to one or more aspects of the present disclosure may be operable to conduct operational health monitoring (e.g., operational health self-diagnostic test) on various operational parameters of a top drive. The operational parameters may include aspects related to rotation function of the top drive. A challenge of conducting operational health monitoring on a rotational function of the top drive is creating load. During typical top drive operations (e.g., torqueing operations, drilling operations), the load experienced by the top drive is highly variable and therefore may not be well suited for health diagnostics. Top drives within the scope of the present disclosure may have one, two, or more rotary actuators for rotating the drive shaft of the top drive.

Top drives having two or more rotary actuators can have each rotary actuator operate independently from one another, wherein the rotary actuators can be operated in different directions, at different speeds, and/or at different loads. Operational health monitoring according to one or more aspects of the present disclosure comprises driving movement with a first rotary actuator (e.g., electric motor) in a predetermined rotational direction while applying load to the first rotary actuator with the second rotary actuator (e.g., electric motor). The result is that both rotary actuators are loaded, with one motor moving forward (running) and the other backwards (braking). Sensor measurements may be taken during the operational health monitoring from which operational health condition may be derived. The operational measurements may be taken by various sensors (e.g., vibration, pressure, temperature, etc.) located within or outside the top drive (e.g., on surface of the top drive, on other related equipment). Current operational measurements may then be compared to historical (baseline) operational measurements. Several (e.g., successive) operational measurements taken over time may be compared to determine current operational health.

FIG. 2 is a schematic view of at least a portion of an example implementation of a monitoring system 200 for monitoring, controlling, and determining operational health of a top drive 202 according to one or more aspects of the present disclosure. The monitoring system 200 may form a portion of or operate in conjunction with the well construction system 100 shown in FIG. 1. For example, the top drive 202 may be or comprise the top drive 116 shown in FIG. 1. The monitoring system 200 may, thus, comprise one or more features of the well construction system 100 shown in FIG. 1, including where indicated by the same numerals. Accordingly, the following description refers to FIGS. 1 and 2, collectively.

The monitoring system 200 may comprise a processing device 204, such as a programmable logic controller (PLC), a computer (PC), an industrial computer (IPC), or a controller equipped with control logic, communicatively connected with various sensors, actuators, and other controllers of the top drive 202 and/or the monitoring system 200. The processing device 204 may be in real-time communication with such sensors, actuators, and other controllers and utilized to monitor and/or control various portions, components, and equipment of the top drive 202. The processing device 204 may be or form at least a portion of the processing device 192 shown in FIG. 1. Communication between the processing device 204 and the sensors, actuators, and other controllers may be via wired and/or wireless communication means 205. However, for clarity and ease of understanding, such communication means 205 are not wholly depicted, and a person having ordinary skill in the art will appreciate that such communication means are within the scope of the present disclosure.

The top drive 202 may be supported by a traveling block 113 operatively connected with and collectively raised by a draw works via a support line 123. The traveling block 113 may comprise a sheave 210 connected to a connection block 212 and reeved to a stationary block via the support line 123. The top drive 202 may be coupled with the travelling block 113 via a plurality (e.g., two, four) of tie rods or links 214 extending between the connection block 212 and the top drive 202. The support line 123 may be stored on a storage reel and tied down by a deadline anchor. The support line 123 may also or instead be stored on a spool of the draw works. An elevator 129 configured to couple with a box end of a single tubular or an upper end (i.e., box end) of the drill string may be connected with the top drive 202 via elevator links 127. As described above, a motor or another rotary actuator (not shown) of the draw works may be operated to rotate the spool to wind or unwind the support line 123 to lift or lower the top drive 202 and, thus, the individual tubulars or drill string during tubular running and drilling operations.

The monitoring system 200 may be utilized to monitor operational health of a top drive 202 comprising two rotary actuators 220, 222 (e.g., electric motors) operatively connected to a drive shaft 125 of the top drive 202 via a transmission or gear box 224. The gear box 224 may comprise a plurality of gears 226, 228, 230 operatively connecting output shafts of the rotary actuators 220, 222 together and collectively operable to transfer torque from the rotary actuators 220, 222 to the drive shaft 125. A plurality of bearings 232 (e.g., ball bearings, thrust bearings, etc.) may be installed or otherwise disposed in association with the gears 226, 228, 230, the drive shaft 125, and/or other portions of the gear box 224. The bearings 232 may reduce friction and, thus, facilitate relative movement (e.g., rotation) between various members of the gear box 224 and reinforce relative positions of such members.

The rotary actuators 220, 222 of the top drive 202 may be controlled and powered (i.e., driven) by corresponding variable frequency drives (VFDs) 240, 242, each communicatively connected with the processing device 204 and electrically connected with a corresponding rotary actuator 220, 222. The VFDs 240, 242 may be disposed or installed in association with the top drive 202. However, the VFDs 240, 242 may instead be disconnected from the top drive 202 and/or located at a distance from the top drive 202, such as within the control center. Each VFD 240, 242 may be operable to control operation (e.g., rotational speed and torque) of the corresponding rotary actuator 220, 222 and, thus, of the top drive 202. Each VFD 240, 242 may control electrical power (e.g., current, voltage, frequency) delivered to the corresponding rotary actuator 220, 222. Each VFD 240, 242 may further calculate and report speed and torque values of the processing device 204. The processing device 204 may determine the speed and/or torque setpoints to be used for an operation, and send the setpoints to the VFDs 240, 242. Communication between the VFDs 240, 242 and the processing device 204 may implemented, for example, via Profibus, Profinet, Ethernet, and/or another communication protocol.

Although the top drive 202 is shown in association with two VFDs 240, 242, the rotary actuators 220, 222 may be controlled by a single VFD having outputs dedicated to each rotary actuator 220, 222. When utilizing two VFDs 240, 242, a leader-follower control scheme may be utilized for load/torque sharing, wherein the first VFD 240 is a “leader” driver that provides control signals to the second “follower” VFD 242. The second VFD 242 may receive a torque setpoint and other control signals and follow/execute them via the second rotary actuator 222. In such implementations, however, there may be a time delay for the control signals sent from the first VFD 240 to reach the second VFD 242, which doesn't occur in implementations in which a single VFD drives multiple rotary actuators 220, 222. The delay time is dependent on the communication devices and protocol utilized.

The monitoring system 200 may further comprise a plurality of sensors 250, 252, 254, each operatively connected with and/or disposed in association with the top drive 202. The sensors 250, 252, 254 may be disposed within or on external surface of corresponding portions of the top drive 202. Each sensor may be operable to generate a sensor signal or information that is indicative of or operable to facilitate determination of a sensor measurement of an operational parameter of the top drive 202. For example, the monitoring system 200 may comprise a plurality of temperature sensors 250 each operable to generate a sensor signal indicative of or operable to facilitate determination of a temperature measurement of a corresponding portion of the top drive 202. The temperature sensors 250 may be disposed or installed in association with, for example, the rotary actuators 220, 222, such as may permit temperature measurement of windings or other portions of the rotary actuators 220, 222. The temperature sensors 250 may be disposed or installed in association with, for example, the gear box 224, such as may permit temperature measurement of various bearings 232 or other portions of the gear box 224. The monitoring system 200 may comprise a plurality of vibration (e.g., acceleration) sensors 252 (e.g., strain gauge accelerometers, piezoelectric vibration sensors, etc.), each operable to generate a sensor signal indicative of or operable to facilitate determination of vibration measurement (e.g., magnitude, frequency, wavelength) of the top drive 202. The vibration sensors 252 may be single axis and/or multi axis vibration sensors disposed or installed in association with, for example, the rotary actuators 220, 222 and the gear box 224. The monitoring system 200 may further comprise a plurality of rotational position sensors 254, each operable to generate a sensor signal indicative of or operable to facilitate determination of rotational position measurements of a corresponding portion of the top drive 202. The rotational position sensors 254 may be disposed or installed in association with, for example, the rotary actuators 220, 222 to monitor rotational positions of the rotary actuators 220, 222, and the gear box 224 to monitor rotational position of the drive shaft 125. The rotational position measurements may be further indicative of rotational speed and rotational acceleration of the rotary actuators 220, 222 and the drive shaft 125. The rotational position sensors 254 may be or comprise, for example, encoders, rotary potentiometers, and rotary variable-differential transformers (RVDTs).

Each VFD 240, 242 may be further operable to calculate or determine torque and/or rotational speed generated or outputted by each rotary actuator 220, 222, such as based on the electrical power (e.g., current, voltage, frequency) delivered to each rotary actuator 220, 222. Each VFD 240, 242 may then generate a signal indicative of or operable to facilitate determination of outputted torque measurement and/or rotational speed measurement of each rotary actuator 220, 222 and transmit the measurement to the processing device 204.

The present disclosure is further directed to example methods or processes of performing operational health monitoring of a top drive comprising two or more rotary actuators, such as the top drive 202, via a monitoring system, such as the monitoring system 200, according to one or more aspects of the present disclosure. The example methods may be performed utilizing or otherwise in conjunction with at least a portion of one or more implementations of one or more instances of the apparatus shown in one or more of FIGS. 1 and 2, and/or otherwise within the scope of the present disclosure. For example, the methods may be performed and/or caused, at least partially, by a processing device, such as the processing device 204 executing program code instructions according to one or more aspects of the present disclosure. The methods may also or instead be performed and/or caused, at least partially, by a human wellsite operator utilizing one or more instances of the apparatus shown in one or more of FIGS. 1 and 2, and/or otherwise within the scope of the present disclosure. Thus, the following description of an example method refers to apparatus shown in one or more of FIGS. 1 and 2. However, the method may also be performed in conjunction with implementations of apparatus other than those depicted in FIGS. 1 and 2 that are also within the scope of the present disclosure.

The method may include commencing operation of the processing device 204 to determine operational health of the top drive 202. The processing device 204 may then output a first control command to a first rotary actuator 220 (e.g., electric motor) of the top drive 202 to cause the first rotary actuator 220 to perform a rotational operation, output a second control command to the second rotary actuator 222 (e.g., electric motor) of the top drive 202 to cause the second rotary actuator 222 to impart a load to the first rotary actuator 220. The processing device 204 may then receive sensor measurement(s) indicative of operational parameter(s) of the top drive 202 facilitated by one or more of the sensors 250, 252, 254 and determine operational health of the top drive 202 based on the sensor measurement(s).

An example rotational operation may comprise operating the first rotary actuator 220 at a constant target rotational speed and a constant target torque while the load imparted by the second rotary actuator 222 is maintained at a constant target level. An example rotational operation may comprise operating the first rotary actuator 220 at an increasing or decreasing rotational speed (ramp-up or ramp-down) and a constant torque while the load imparted by the second rotary actuator 222 decreases or increases (ramps down or ramps up), respectively. An example rotational operation may comprise operating the first rotary actuator 220 at a constant rotational speed and an increasing or decreasing torque while the load imparted by the second rotary actuator 222 increases or decreases, respectively. Another example rotational operation may comprise a combination of the rotational operations described above.

To impart a load to the first rotary actuator 220 by the second rotary actuator 222, the second control command outputted by the processing device 204 may cause the second rotary actuator 222 to output a torque that is lesser than, but opposes rotation and torque of the first rotary actuator 220. The second rotary actuator 222 may instead be caused by the processing device 204 to try to maintain a static position (perhaps with selectively variable level of resistance), thereby resisting rotation of the first rotary actuator 220 (with selectively variable level of resistance). The second rotary actuator 222 may instead be caused by the processing device 204 to rotate at a rotational speed that is slower than and/or at a rotational phase that lags behind rotational phase of the first rotary actuator 220, thereby resisting rotation of the first rotary actuator 220.

The operational health monitoring operations described above may then be reversed wherein the second rotary actuator 222 performs a rotational operation and the first rotary actuator 220 imparts a load to the first rotary actuator 220. For example, the processing device 204 may output a third control command to the second rotary actuator 222 to cause the second rotary actuator 222 to perform a rotational operation and output a fourth control command to the first rotary actuator 220 to cause the first rotary actuator 220 to impart a load to the second rotary actuator 222. The rotational operation may be a selected one of the rotational operations described above or a combination of such rotational operations. The processing device 204 may then receive sensor measurement(s) indicative of operational parameter(s) of the top drive 202 and determine the operational health of the top drive 202 further based on the sensor measurement(s).

The processing device 204 may further record the sensor measurement(s) during such rotational operations over a period of time (e.g., a minute, several minutes). The rotational operations and the recording of the corresponding sensor measurement(s) may be performed at predetermined time intervals (e.g., daily, weekly, monthly, etc.). Newly acquired or received sensor measurement(s) (current sensor measurements) may then be compared to previously recorded sensor measurement(s). The operational health of the top drive 202 may be determined based on the comparisons. The processing device 204 may determine the operational health of the top drive 202 by comparing the current sensor measurement(s) to previously recorded sensor measurement(s) indicative of operational parameter(s) of the top drive 202 to determine a difference between the current sensor measurement(s) and the previously recorded sensor measurement(s). For example, the processing device 204 may determine the operational health of the top drive 202 by comparing the current sensor measurement(s) to baseline sensor measurement(s) that was/were recorded when the top drive 202 was new or repaired.

The processing device 204 may then determine the operational health of the top drive 202 based on the comparison. For example, the processing device 204 may determine that the top drive 202 is operationally healthy when the current sensor measurement(s) and the previously recorded (baseline) sensor measurement(s) are substantially equal. The processing device 204 may instead determine that the top drive 202 is operationally unhealthy when the current sensor measurement(s) and the previously recorded sensor measurement(s) are appreciably different. The processing device 204 may also or instead determine that the top drive 202 is operationally unhealthy when difference(s) between the current sensor measurement(s) and the previously recorded sensor measurement(s) is/are equal to or greater than predetermined threshold quantity or quantities.

Operational health monitoring according to one or more aspects of the present disclosure may further comprise driving movement with a rotary actuator (e.g., electric motor) of a top drive in a predetermined rotational direction while applying load to the rotary actuator. The load may be applied to the actuator with an external loading device operatively or otherwise mechanically connected to a drive shaft of the top drive. Such connection to an external loading device may be utilized to apply a load to and monitor operational health of a top drive having a single rotary actuator and a top drive having two or more rotary actuators. Sensor measurements may be taken during the operational health monitoring from which operational health condition may be derived. The operational measurements may be taken by various sensors (e.g., vibration, pressure, temperature, etc.) located within or outside the top drive. Current operational measurements may then be compared to historical (baseline) operational measurements. Several (e.g., successive) operational measurements taken over time may be compared to determine current operational health.

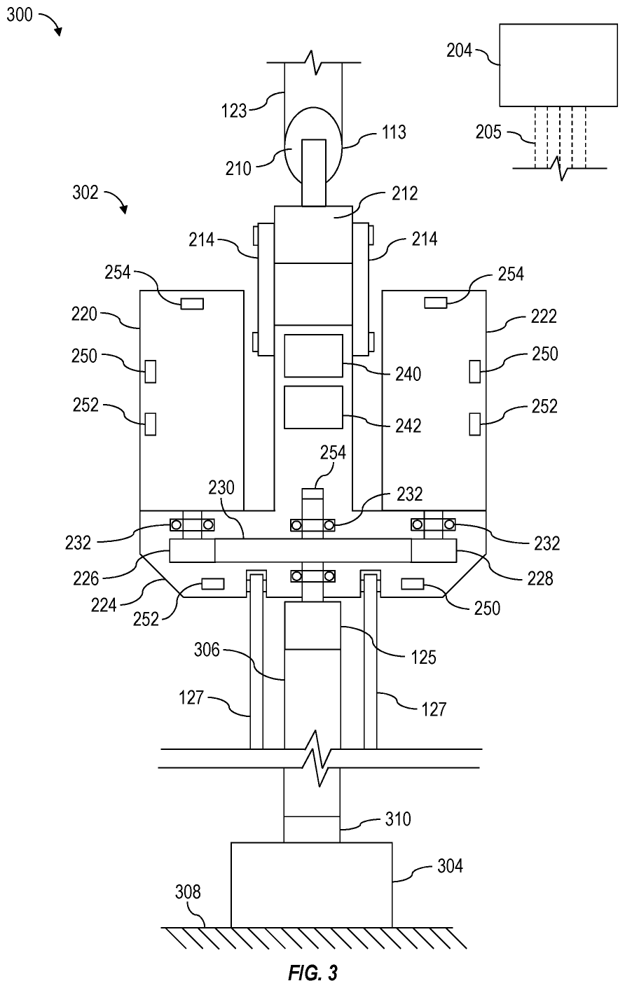

FIG. 3 is a schematic view of at least a portion of an example implementation of a monitoring system 300 for monitoring, controlling, and determining operational health of a top drive 302 according to one or more aspects of the present disclosure. The monitoring system 300 may form a portion of or operate in conjunction with the well construction system 100 shown in FIG. 1. For example, the top drive 302 may be or comprise the top drive 116 shown in FIG. 1. The monitoring system 300 may, thus, comprise one or more features of the well construction system 100 shown in FIG. 1, including where indicated by the same numerals. The monitoring system 300 may also comprise one or more features of the well monitoring system 200 shown in FIG. 2, including where indicated by the same numerals. Accordingly, the following description refers to FIGS. 1 and 3, collectively.

Although the top drive 302 is shown comprising two rotary actuators 220, 222, it is to be understood that the top drive 302 may be implemented with a single rotary motor, such as one of the rotary actuators 220, 222. Thus, the monitoring system 300 may be operable to monitor, control, and determine operational health of a top drive 302 comprising a single rotary actuator.

The drive shaft 125 of the top drive 302 may be operatively or otherwise mechanically connected with a loading device 304 operable to impart a load to one or both of the rotary actuators 220, 222 of the top drive 302. For example, the loading device 304 may be connected with the drive shaft 125 via a torque transfer shaft 306 extending between the loading device 304 and the drive shaft 125. The torque transfer shaft 306 may be coupled with the loading device 304 and detachably engaged or coupled with the drive shaft 125 (e.g., the threaded portion of the drive shaft 125). The loading device 304 may be fixedly connected with a base 308, which may prevent or inhibit rotation of at least a portion of the loading device 304 when torque is being transferred from the top drive 302 to the loading device 304. The base 308 may be, for example, the rig floor, the support structure, and/or the body of the top drive 302.

The monitoring system 300 may further comprise a torque sensor 310 operable to generate a signal indicative of or operable to facilitate determination of torque measurement that was outputted by the top drive 302 via the drive shaft 125 to the loading device 304 and transmit the measurement to the processing device 204. The torque sensor 310 may be mechanically connected or otherwise disposed between the drive shaft 125 and the loading device 304, such as may permit the torque sensor 310 to transfer and measure the torque. The torque sensor 310 may also facilitate determination of rotational position, speed, and acceleration of the drive shaft 125.

The loading device 304 may include a device that is controllable by the processing device 204 to impart a predetermined or changing load to one or both rotary actuators 220, 222 of the top drive 302. For example, the loading device 304 may be or comprise an electric motor selectively controllable by the processing device 204 via a VFD (not shown) corresponding to the loading device 304.

The loading device 304 may be or comprise a mechanical brake selectively controllable by the processing device 204. The mechanical brake may be or comprise a hydraulic brake, which may use hydraulic fluid to generate resistance to cause a rotational load. The hydraulic brake may comprise a hydraulic pump connected to the drive shaft 125 and a flow restrictor for controlling hydraulic fluid flow rate and, thus, resistance to rotation of the drive shaft. The hydraulic brake may comprise opposing hydraulic turbines coupled with hydraulic fluid (e.g., fluid coupling, fluid clutch), wherein one is connected to the base and the other is connected with the drive shaft 125, perhaps via the torque transfer shaft 306. The load generated by the hydraulic brake may be controlled by controlling the distance between the hydraulic turbines. The mechanical brake may be or comprise a friction brake, which may comprise friction pads configured to create load. Friction resistance may be used to create rotational load. The mechanical brake may be or comprise, for example, hydraulic park brakes of the top drive 302 located in association with a rotary actuator 220, 222 of the top drive 302. Such brakes may be or comprise multi-disc brakes whereby hydraulic pressure is used to engage the friction pads of the friction brake. Each friction pad may be biased by a set of springs, which may release a friction pad when the hydraulic pressure is released or falls below operating pressure. Monitoring of the friction brake may be accomplished by monitoring the hydraulic pressure. If the hydraulic pressure feedback does not comply with a park brake output status, a brake fault alarm may be initiated.

The loading device 304 may be or comprise an electro-mechanical brake selectively controllable by the processing device 204. The electro-mechanical brake may be or comprise a magnetic brake, such as operable to generate a magnetic field to create a rotational load. The electro-mechanical brake may be or comprise a device operable to create a rotational load by creating an electrical load. For example, an electric generator may be mechanically connected to the drive shaft 125 and electrically is connected to a bleed-off circuit. The loading device 304 may be or comprise a combination of the loading devices 304 described above.

The loading device 304 may be or comprise a piece of surface equipment 110 of the well construction system 100. For example, the loading device 304 may be or comprise a rotary table for rotating the drill string via a kelly. The rotary table may be coupled to the drive shaft 125 of the top drive 302 via the torque transfer shaft 306. The top drive 203 may then perform rotational operations against the load imparted by the rotary table. The loading device 304 may be or comprise a torqueing device for making up and breaking out pipe connections. The torqueing device may be an iron roughneck, which may be coupled to the drive shaft 125 via the torque transfer shaft 306. The top drive 203 may then perform rotational operations against the load imparted by the torqueing device.

The loading device 304 may be or comprise a rotational mass connected with the drive shaft 125. The rotational mass may operate similarly to a momentum flywheel and used to impart a load to the top drive 302 while the top drive 302 is accelerating and/or decelerating rotation (i.e., imparting or absorbing angular momentum) of the rotational mass.

The present disclosure is further directed to example methods or processes of performing operational health monitoring of a top drive comprising one, two, or more rotary actuators, such as the top drive 302, via a monitoring system, such as the monitoring system 300, according to one or more aspects of the present disclosure. The example methods may be performed utilizing or otherwise in conjunction with at least a portion of one or more implementations of one or more instances of the apparatus shown in one or more of FIGS. 1 and 3, and/or otherwise within the scope of the present disclosure. For example, the methods may be performed and/or caused, at least partially, by a processing device, such as the processing device 204 executing program code instructions according to one or more aspects of the present disclosure. The methods may also or instead be performed and/or caused, at least partially, by a human wellsite operator utilizing one or more instances of the apparatus shown in one or more of FIGS. 1 and 3, and/or otherwise within the scope of the present disclosure. Thus, the following description of an example method refers to apparatus shown in one or more of FIGS. 1 and 3. However, the method may also be performed in conjunction with implementations of apparatus other than those depicted in FIGS. 1 and 3 that are also within the scope of the present disclosure.

The method may include commencing operation of the processing device 204 to determine operational health of the top drive 302. The processing device 204 may then output a first control command to one or both of the rotary actuators 220, 222 (e.g., electric motors) of the top drive 302 to cause the rotary actuator(s) 220, 222 to perform a rotational operation, output a second control command to the loading device 304 to cause the loading device 304 to impart a load to the rotary actuator(s) 220, 222. The processing device 204 may then receive sensor measurement(s) indicative of operational parameter(s) of the top drive 302 facilitated by one or more of the sensors 250, 252, 254 and determine operational health of the top drive 302 based on the sensor measurement(s). If the top drive 302 comprises just one rotary actuator, then control commands during operational health monitoring may be sent just to the one rotary actuator.

An example rotational operation may comprise operating the rotary actuator(s) 220, 222 at a constant target rotational speed and a constant target torque while the load imparted by the loading device 304 is maintained at a constant target level. An example rotational operation may comprise operating the rotary actuator(s) 220, 222 at an increasing or decreasing rotational speed (ramp-up or ramp-down) and a constant torque while the load imparted by the loading device 304 decreases or increases (ramps down or ramps up), respectively. An example rotational operation may comprise operating the rotary actuator(s) 220, 222 at a constant rotational speed and an increasing or decreasing torque while the load imparted by the loading device 304 increases or decreases, respectively. Another example rotational operation may comprise a combination of the rotational operations described above.

To impart a load to the rotary actuator(s) 220, 222 by the loading device 304, the second control command outputted by the processing device 204 may cause the loading device 304 to output a torque that is lesser than, but opposes rotation and torque of the rotary actuator(s) 220, 222. The loading device 304 may instead be caused by the processing device 204 to try to maintain a static position (perhaps with selectively variable level of resistance), thereby resisting rotation of the rotary actuator(s) 220, 222 (with selectively variable level of resistance). The loading device 304 may instead be caused by the processing device 204 to rotate at a rotational speed that is slower than and/or at a rotational phase that lags behind rotational phase of the rotary actuator(s) 220, 222, thereby resisting rotation of the rotary actuator(s) 220, 222.

If one of the rotary actuators 220, 222 has undergone the operational health monitoring, the operational health monitoring operations described above may then be reversed, wherein the other of the rotary actuators 220, 222 performs a rotational operation while the loading device 304 imparts a load to the other rotary actuator 220, 222. For example, the processing device 204 may output a third control command to the other rotary actuator 220, 222 to cause the other rotary actuator 220, 222 to perform a rotational operation and output a fourth control command to the loading device 304 to cause the loading device 304 to impart a load to the other rotary actuator 220, 222. The rotational operation may be a selected one of the rotational operations described above or a combination of such rotational operations. The processing device 204 may then receive sensor measurement(s) indicative of operational parameter(s) of the top drive 302 and determine the operational health of the top drive 302 further based on the sensor measurement(s).

The processing device 204 may further record the sensor measurement(s) during such rotational operations over a period of time (e.g., a minute, several minutes). The rotational operations and the recording of the corresponding sensor measurement(s) may be performed at predetermined time intervals (e.g., daily, weekly, monthly, etc.). Newly acquired or received sensor measurement(s) (current sensor measurements) may then be compared to previously recorded sensor measurement(s). The operational health of the top drive 302 may be determined based on the comparison. The processing device 204 may determine the operational health of the top drive 302 by comparing the current sensor measurement(s) to previously recorded sensor measurement(s) indicative of operational parameter(s) of the top drive 302 to determine a difference between the current sensor measurement(s) and the previously recorded sensor measurement(s). For example, the processing device 204 may determine the operational health of the top drive 302 by comparing the current sensor measurement(s) to base sensor measurement(s) that was/were recorded when the top drive 302 was newly manufactured or repaired.

The processing device 204 may then determine the operational health of the top drive 302 based on the comparison. For example, the processing device 204 may determine that the top drive 302 is operationally healthy when the current sensor measurement(s) and the previously recorded (baseline) sensor measurement(s) are substantially equal. The processing device 204 may instead determine that the top drive 302 is operationally unhealthy when the current sensor measurement(s) and the previously recorded sensor measurement(s) are appreciably different. The processing device 204 may also or instead determine that the top drive 302 is operationally unhealthy when difference(s) between the current sensor measurement(s) and the previously recorded sensor measurement(s) is/are equal to or greater than predetermined threshold quantity or quantities.

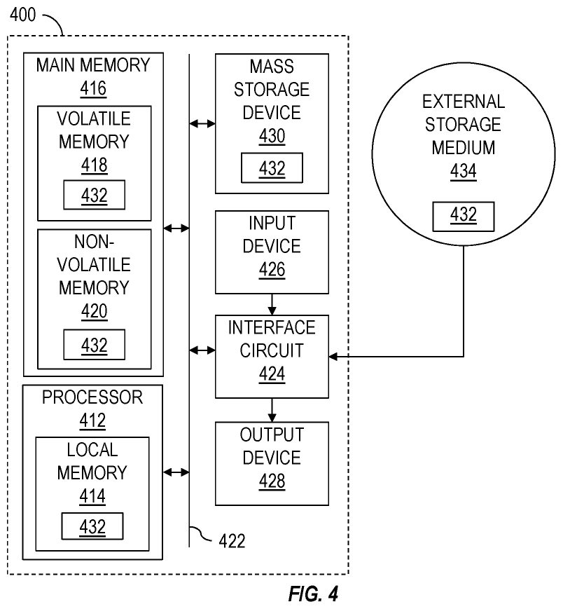

FIG. 4 is a schematic view of at least a portion of an example implementation of a processing system 400 (or device) according to one or more aspects of the present disclosure. The processing system 400 may be or form at least a portion of one or more processing devices, equipment controllers, and/or other electronic devices shown in one or more of the FIGS. 1-3. Accordingly, the following description refers to FIGS. 1-4, collectively.

The processing system 400 may be or comprise, for example, one or more processors, controllers, special-purpose computing devices, PCs (e.g., desktop, laptop, and/or tablet computers), personal digital assistants, smartphones, IPCs, PLCs, servers, internet appliances, and/or other types of computing devices. The processing system 400 may be or form at least a portion of the processing device 192, 204. The processing system 400 may be or form at least a portion of the local controllers, such as the VFDs 240, 242. Although it is possible that the entirety of the processing system 400 is implemented within one device, it is also contemplated that one or more components or functions of the processing system 400 may be implemented across multiple devices, some or an entirety of which may be at the wellsite and/or remote from the wellsite.

The processing system 400 may comprise a processor 412, such as a general-purpose programmable processor. The processor 412 may comprise a local memory 414, and may execute machine-readable and executable program code instructions 432 (i.e., computer program code) present in the local memory 414 and/or another memory device. The processor 412 may execute, among other things, the program code instructions 432 and/or other instructions and/or programs to implement the example methods, processes, and/or operations described herein. For example, the program code instructions 432, when executed by the processor 412 of the processing system 400, may cause a top drive 116, 202, 302 and/or a loading device 304 to perform the example methods and/or operations described herein. The program code instructions 432, when executed by the processor 412 of the processing system 400, may also or instead cause the processor 412 to receive, record, and process sensor data (e.g., sensor measurements), compare the sensor data, and output data and/or information indicative of operational health the top drive 116, 202, 302.

The processor 412 may be, comprise, or be implemented by one or more processors of various types suitable to the local application environment, and may include one or more of general-purpose computers, special-purpose computers, microprocessors, digital signal processors (DSPs), field-programmable gate arrays (FPGAs), application-specific integrated circuits (ASICs), and processors based on a multi-core processor architecture, as non-limiting examples. Examples of the processor 412 include one or more INTEL microprocessors, microcontrollers from the ARM and/or PICO families of microcontrollers, embedded soft/hard processors in one or more FPGAs.

The processor 412 may be in communication with a main memory 416, such as may include a volatile memory 418 and a non-volatile memory 420, perhaps via a bus 422 and/or other communication means. The volatile memory 418 may be, comprise, or be implemented by random access memory (RAM), static random access memory (SRAM), synchronous dynamic random access memory (SDRAM), dynamic random access memory (DRAM), RAMBUS dynamic random access memory (RDRAM), and/or other types of random access memory devices. The non-volatile memory 420 may be, comprise, or be implemented by read-only memory, flash memory, and/or other types of memory devices. One or more memory controllers (not shown) may control access to the volatile memory 418 and/or non-volatile memory 420.

The processing system 400 may also comprise an interface circuit 424, which is in communication with the processor 412, such as via the bus 422. The interface circuit 424 may be, comprise, or be implemented by various types of standard interfaces, such as an Ethernet interface, a universal serial bus (USB), a third generation input/output (3GIO) interface, a wireless interface, a cellular interface, and/or a satellite interface, among others. The interface circuit 424 may comprise a graphics driver card. The interface circuit 424 may comprise a communication device, such as a modem or network interface card to facilitate exchange of data with external computing devices via a network (e.g., Ethernet connection, digital subscriber line (DSL), telephone line, coaxial cable, cellular telephone system, satellite, etc.).

The processing system 400 may be in communication with various sensors, video cameras, actuators, processing devices, equipment controllers, and other devices of the well construction system via the interface circuit 424. The interface circuit 424 can facilitate communications between the processing system 400 and one or more devices by utilizing one or more communication protocols, such as an Ethernet-based network protocol (such as ProfiNET, OPC, OPC/UA, Modbus TCP/IP, EtherCAT, UDP multicast, Siemens S7 communication, or the like), a proprietary communication protocol, and/or another communication protocol.

One or more input devices 426 may also be connected to the interface circuit 424. The input devices 426 may permit human wellsite operators 195 to enter the program code instructions 432, which may be or comprise control commands, operational parameters, rotational operations, rotational loading operations, operational health thresholds, and/or other operational setpoints. The program code instructions 432 may further comprise modeling or predictive routines, equations, algorithms, processes, applications, and/or other programs operable to perform example methods and/or operations described herein. The input devices 426 may be, comprise, or be implemented by a keyboard, a mouse, a joystick, a touchscreen, a track-pad, a trackball, an isopoint, and/or a voice recognition system, among other examples. One or more output devices 428 may also be connected to the interface circuit 424. The output devices 428 may permit for visualization or other sensory perception of various data, such as sensor data, status data, and/or other example data. The output devices 428 may be, comprise, or be implemented by video output devices (e.g., an LCD, an LED display, a CRT display, a touchscreen, etc.), printers, and/or speakers, among other examples. The one or more input devices 426 and the one or more output devices 428 connected to the interface circuit 424 may, at least in part, facilitate the HMIs described herein.

The processing system 400 may comprise a mass storage device 430 for storing data and program code instructions 432. The mass storage device 430 may be connected to the processor 412, such as via the bus 422. The mass storage device 430 may be or comprise a tangible, non-transitory storage medium, such as a floppy disk drive, a hard disk drive, a compact disk (CD) drive, and/or digital versatile disk (DVD) drive, among other examples. The processing system 400 may be communicatively connected with an external storage medium 434 via the interface circuit 424. The external storage medium 434 may be or comprise a removable storage medium (e.g., a CD or DVD), such as may be operable to store data and program code instructions 432.

As described above, the program code instructions 432 and other data (e.g., sensor data or measurements database) may be stored in the mass storage device 430, the main memory 416, the local memory 414, and/or the removable storage medium 434. Thus, the processing system 400 may be implemented in accordance with hardware (perhaps implemented in one or more chips including an integrated circuit, such as an ASIC), or may be implemented as software or firmware for execution by the processor 412. In the case of firmware or software, the implementation may be provided as a computer program product including a non-transitory, computer-readable medium or storage structure embodying computer program code instructions 432 (i.e., software or firmware) thereon for execution by the processor 412. The program code instructions 432 may include program instructions or computer program code that, when executed by the processor 412, may perform and/or cause performance of example methods, processes, and/or operations described herein.

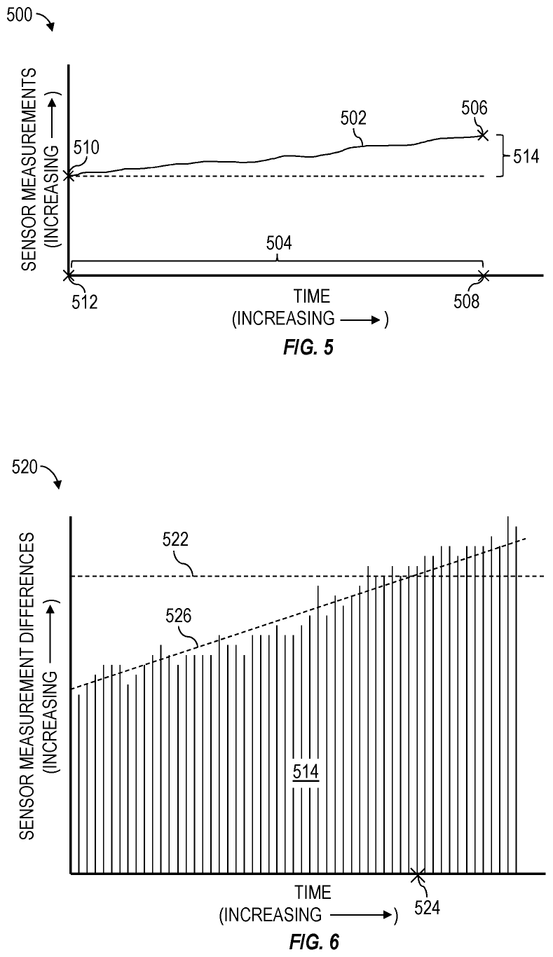

FIG. 5 is a graph 500 showing an example profile of recorded sensor measurements 502 received and recorded over a period of time 504 by a processing device. The sensor measurements 502 are shown plotted along the vertical axis, with respect to time, which is shown plotted along the horizontal axis. The sensor measurements 502 may be indicative of an operational parameter of a top drive, such as temperature level, vibration magnitude, frequency, wavelength, rotational speed, or torque, among other examples. The sensor measurements 502 may be recorded as part of or while the operational health monitoring operations described herein are performed. The operational health monitoring operations may be performed periodically (e.g., each day, each few days, each week, after each job, etc.) for a period of time 504 (e.g., a week, a month, a year, several wellsite jobs, etc.).

The processing device may periodically compare a currently (or most recently) received and/or recorded sensor measurement to one or more previously recorded sensor measurements 502. The current sensor measurement 506 received and/or recorded by the processing device at a current (or most recent) time 508 may be compared to one or more previously recorded sensor measurements 502, such as a baseline sensor measurement 510 that was recorded by the processing device at time 512. For example, the baseline sensor measurement 510 may be a sensor measurement that was recorded at a time 512 when the top drive or a portion of the top drive was new or just repaired. Therefore, the baseline sensor measurement 510 may comprise a level or another characteristic associated with a fully or otherwise optimally functional top drive or portion thereof. The processing device may then compare the current sensor measurement 506 to the baseline sensor measurement 510 to determine a difference 514 between the current sensor measurement 506 and the baseline sensor measurement 510. The determined difference 514 may be recorded to a database by the processing device. The processing device may then determine operational health of the top drive or portion thereof based on the comparison. The processing device may determine the difference 514 between a current sensor measurement 506 and the baseline sensor measurement 510 and the operational health of the top drive or portion thereof based on the difference 514 periodically (e.g., each time the operational health monitoring operations are performed).

For example, if the current sensor measurement 506 and the baseline sensor measurement 510 are substantially similar or match each other, then the top drive or portion thereof may be deemed or otherwise determined as being operationally healthy. However, if the current sensor measurement 506 and the baseline sensor measurement 510 are appreciably different, not substantially similar, or otherwise do not substantially match, then the top drive or portion thereof may be deemed or otherwise determined as being operationally unhealthy (e.g., degraded, worn, leaking, loose, inefficient, etc.). The top drive or portion thereof may be deemed or otherwise determined as being operationally unhealthy, for example, when a difference 514 (e.g., in profile and/or magnitude) between the current sensor measurement 506 and the baseline sensor measurement 510 is equal to or greater than a predetermined threshold amount or is otherwise appreciable. If the top drive or a portion thereof associated with the current and baseline sensor measurements 506, 510 was deemed or otherwise determined as being operationally unhealthy, such top drive or portion thereof may then be replaced or repaired.

The sensor measurements 502 may be indicative of various operational parameters of the top drive, and may be indicative of operational problems of different portions of the top drive corresponding to the location of the sensors facilitating such sensor measurements. For example, the sensor measurements 502 may be or comprise temperature sensor measurements indicative of temperature of a portion of the top drive corresponding to the location of the temperature sensors facilitating the temperature sensor measurements. The sensor measurements 502 may be indicative of temperature of motor windings, bearings, and/or hydraulic fluid, among other examples. Thus, a difference between a baseline temperature sensor measurement and current temperature sensor measurement may be indicative of an operational problem or degradation (e.g., excessive friction, low hydraulic fluid level) associated with a portion of the top drive corresponding to the temperature sensors facilitating the temperature sensor measurements. Similarly, the sensor measurements 502 may be or comprise vibration sensor measurements indicative of vibrations generated by a portion of the top drive corresponding to the location of the vibration sensors facilitating the vibration sensor measurements. For example, the sensor measurements 502 may be indicative of vibrations of a rotary actuator, bearings, and/or a gear box. Thus, a difference between a baseline vibration sensor measurement and current vibration sensor measurement may be indicative of an operational problem or degradation (e.g., worn bearings, worn or broken gears, low hydraulic fluid level) associated with a portion of the top drive corresponding to the vibration sensors facilitating the vibration sensor measurements.

Although the sensor measurements 502 are shown increasing with respect to the baseline sensor measurement 510, operational problem or degradation may be indicated by decreasing sensor measurements. For example, sensor measurements recorded by the processing device may be or comprise rotational speed sensor measurements indicative of rotational speed of a portion of the top drive corresponding to the location of the rotational sensors facilitating the rotational speed sensor measurements. The rotational speed sensor measurements may be indicative of rotational speed of a rotary actuator, a gear, and/or a drive shaft, among other examples. Thus, decreasing speed sensor measurements resulting in a difference between a baseline rotational speed sensor measurement and current rotational speed sensor measurement may be indicative of an operational problem or degradation (e.g., worn rotary actuator, deteriorating motor windings, excessive friction) associated with a portion of the top drive corresponding to the rotational speed sensors facilitating the rotational speed sensor measurements.

FIG. 6 is a graph 520 showing a plurality sensor measurement differences 514, as described above and shown in FIG. 5, recorded over time. The sensor measurement differences 514 are shown plotted along the vertical axis, with respect to time, which is shown plotted along the horizontal axis. The graph 520 may be generated by the processing device, such as the processing device 204, shown in FIGS. 2 and 3, based on recorded historical and current sensor measurement differences 514. The following description refers to FIGS. 1-5, collectively.

The graph 520 shows that the differences 514 between recorded current sensor measurements 506 and a baseline sensor measurement 510 are progressively increasing each time a sensor measurement difference 514 is calculated, such as during operational health monitoring operations. Such trend may be indicative of declining operational health (i.e., condition) of the top drive or a portion thereof associated with the sensors facilitating the sensor measurements 502 from which the differences were calculated.

The processing device may generate or otherwise output condition information indicative of the operational health of the top drive or a portion thereof. For example, the processing device may output information indicative of which portion of the top drive is operationally unhealthy. The processing device may also or instead output operational condition information indicative of remaining life of the top drive or a portion thereof. Furthermore, a threshold of acceptable operational health, indicated by line 522, may be set by a wellsite operator 195, such as based on historical maintenance data. Accordingly, if a predetermined number of consecutive sensor measurement differences 514 meet or exceed the threshold 522, such as at time 524, the processing device may at such time 524 output operational health information suggesting or mandating that maintenance of the top drive or a portion thereof be performed. Furthermore, if a running average of the measurement differences 514, indicated by line 526, meets or exceeds the threshold 522, such as at time 524, the processing device may at such time 524 output operational health information suggesting or mandating that maintenance of the top drive or a portion thereof be performed. However, if the sensor measurement differences 514 do not consistently meet or exceed the threshold 522 and/or if the running average 526 of the sensor measurement differences 514 does not meet or exceed the threshold 522, then the top drive or portion thereof may be deemed or otherwise determined by the processing device as being operationally healthy.

In view of the entirety of the present disclosure, including the figures and the claims, a person having ordinary skill in the art will readily recognize that the present disclosure introduces an apparatus comprising a system for monitoring operational health of a top drive operable to rotate a drill string at a wellsite, wherein the system comprises: a sensor operatively connected with and/or disposed in association with the top drive and operable to facilitate determination of a sensor measurement of an operational parameter of the top drive; a loading device detachably connected to a drive shaft of the top drive and operable to impart a load to a motor of the top drive; and a processing device comprising a processor and a memory storing computer program code, wherein the processing device is communicatively connected with the sensor and the loading device, and wherein the processing device is operable to: output a first control command to the motor to cause the motor to perform a rotational operation; output a second control command to the loading device to cause the loading device to impart a load to the motor; receive the sensor measurement; and determine operational health of the top drive based on the sensor measurement.

The processing device may be further operable to: record the sensor measurement over a period of time; compare the sensor measurement that is currently received to a sensor measurement that was recorded; and determine the operational health of the top drive based on the comparison.

The sensor measurement may be a current sensor measurement, and the processing device may be further operable to determine the operational health of the top drive by comparing the current sensor measurement to a previously recorded sensor measurement indicative of the operational parameter of the top drive to determine a difference between the current sensor measurement and the previously recorded sensor measurement. The processing device may be operable to determine that the top drive is operationally healthy when the current sensor measurement and the previously recorded sensor measurement are substantially equal. The processing device may be operable to determine that the top drive is operationally unhealthy when the current sensor measurement and the previously recorded sensor measurement are appreciably different. The processing device may be operable to determine that the top drive is operationally unhealthy when a difference between the current sensor measurement and the previously recorded sensor measurement is equal to or greater than a predetermined threshold quantity.

The rotational operation may comprise operating the motor at a constant rotational speed and a constant torque, and the load imparted by the loading device is maintained at a constant level.

The rotational operation may comprise operating the motor at an increasing rotational speed and a constant torque, and the load imparted by the loading device decreases.

The rotational operation may comprise operating the motor at a constant rotational speed and an increasing torque, and the load imparted by the loading device increases.

The sensor measurement may be or comprise a temperature measurement and the operational parameter may be or comprise temperature of the top drive, the sensor measurement may be or comprise a vibration measurement and the operational parameter may be or comprise vibration of the top drive, the sensor measurement may be or comprise a rotational speed measurement and the operational parameter may be or comprise rotational speed of the motor or the drive shaft, or the sensor measurement may be or comprise a torque measurement and the operational parameter may be or comprise torque outputted by the motor or the drive shaft.

The loading device may be or comprise at least one of: an electric motor; an electric generator; a mechanical brake; a hydraulic brake; a rotary table for rotating the drill string; and a torqueing device for making up and breaking out pipe connections.

The present disclosure also introduces a method comprising commencing operation of a processing device to determine operational health of a top drive for rotating a drill string at a wellsite, wherein the processing device: outputs a first control command to a motor of the top drive to cause the motor to perform a rotational operation; outputs a second control command to a loading device coupled to a drive shaft of the top drive to cause the loading device to impart a load to the motor; receives a sensor measurement indicative of an operational parameter of the top drive; and determines operational health of the top drive based on the sensor measurement.

The processing device may further: record the sensor measurement over a period of time; compare the sensor measurement that is currently received to a sensor measurement that was recorded; and determine the operational health of the top drive based on the comparison.

The sensor measurement may be a current sensor measurement, and the processing device may determine the operational health of the top drive by comparing the current sensor measurement to a previously recorded sensor measurement indicative of the operational parameter of the top drive to determine a difference between the current sensor measurement and the previously recorded sensor measurement. Determining the operational health of the top drive may comprise determining that the top drive is operationally healthy when the current sensor measurement and the previously recorded sensor measurement are substantially equal. Determining the operational health of the top drive may comprise determining that the top drive is operationally unhealthy when the current sensor measurement and the previously recorded sensor measurement are appreciably different. Determining the operational health of the top drive may comprise determining that the top drive is operationally unhealthy when a difference between the current sensor measurement and the previously recorded sensor measurement is equal to or greater than a predetermined threshold quantity.

The rotational operation may comprise operating the motor at a constant rotational speed and a constant torque, and the load imparted by the loading device is maintained at a constant level.

The rotational operation may comprise operating the motor at an increasing rotational speed and a constant torque, and the load imparted by the loading device decreases.

The rotational operation may comprise operating the motor at a constant rotational speed and an increasing torque, and the load imparted by the loading device increases.

The sensor measurement may be or comprise a temperature measurement and the operational parameter may be or comprise temperature of the top drive.

The sensor measurement may be or comprise a vibration measurement and the operational parameter may be or comprise vibration of the top drive.

The sensor measurement may be or comprise a rotational speed measurement and the operational parameter may be or comprise rotational speed of the motor or the drive shaft.

The sensor measurement may be or comprise a torque measurement and the operational parameter may be or comprise torque outputted by the motor or the drive shaft.

The loading device may be or comprise at least one of: an electric motor; an electric generator; a mechanical brake; a hydraulic brake; a rotary table for rotating the drill string; and a torqueing device for making up and breaking out pipe connections.

The present disclosure also introduces a method comprising commencing operation of a processing device to determine operational health of a top drive for rotating a drill string at a wellsite, wherein the processing device: outputs a first control command to a first motor of the top drive to cause the first motor to perform a rotational operation; outputs a second control command to a second motor of the top drive to cause the second motor to impart a load to the first motor; receives a sensor measurement indicative of an operational parameter of the top drive; and determines operational health of the top drive based on the sensor measurement.

The processing device may further: record the sensor measurement over a period of time; compare the sensor measurement that is currently received to a sensor measurement that was recorded; and determine the operational health of the top drive based on the comparison.

The sensor measurement may be a current sensor measurement, and the processing device may determine the operational health of the top drive by comparing the current sensor measurement to a previously recorded sensor measurement indicative of the operational parameter of the top drive to determine a difference between the current sensor measurement and the previously recorded sensor measurement. Determining the operational health of the top drive may comprise determining that the top drive is operationally healthy when the current sensor measurement and the previously recorded sensor measurement are substantially equal. Determining the operational health of the top drive may comprise determining that the top drive is operationally unhealthy when the current sensor measurement and the previously recorded sensor measurement are appreciably different. Determining the operational health of the top drive may comprise determining that the top drive is operationally unhealthy when a difference between the current sensor measurement and the previously recorded sensor measurement is equal to or greater than a predetermined threshold quantity.

The rotational operation may comprise operating the first motor at a constant rotational speed and a constant torque, and the load imparted by the second motor is maintained at a constant level.

The rotational operation may comprise operating the first motor at an increasing rotational speed and a constant torque, and the load imparted by the second motor decreases.

The rotational operation may comprise operating the first motor at a constant rotational speed and an increasing torque, and the load imparted by the second motor increases.

The rotational operation may be a first rotational operation, the load may be a first load, the sensor measurement may be a first sensor measurement, the operational parameter may be a first operational parameter, and the processing device may further: output a third control command to the second motor to cause the second motor to perform a second rotational operation; output a fourth control command to the first motor to cause the first motor to impart a second load to the second motor; receive a second sensor measurement indicative of a second operational parameter of the top drive; and determine the operational health of the top drive further based on the second sensor measurement.

The sensor measurement may be or comprise a temperature measurement and the operational parameter may be or comprise temperature of the top drive.

The sensor measurement may be or comprise a vibration measurement and the operational parameter may be or comprise vibration of the top drive.

The sensor measurement may be or comprise a rotational speed measurement and the operational parameter may be or comprise rotational speed of the first motor or second motor.

The sensor measurement may be or comprise a torque measurement and the operational parameter may be or comprise torque outputted by the first motor or second motor.

The foregoing outlines features of several embodiments so that a person having ordinary skill in the art may better understand the aspects of the present disclosure. A person having ordinary skill in the art should appreciate that they may readily use the present disclosure as a basis for designing or modifying other processes and structures for carrying out the same functions and/or achieving the same benefits of the embodiments introduced herein. A person having ordinary skill in the art should also realize that such equivalent constructions do not depart from the spirit and scope of the present disclosure, and that they may make various changes, substitutions and alterations herein without departing from the spirit and scope of the present disclosure.

The Abstract at the end of this disclosure is provided to comply with 37 C.F.R. § 1.72(b) to permit the reader to quickly ascertain the nature of the technical disclosure. It is submitted with the understanding that it will not be used to interpret or limit the scope or meaning of the claims.

What is claimed is:

1. An apparatus comprising:
a system for monitoring operational health of a top drive operable to rotate a drill string at a wellsite, wherein the system comprises:
a sensor operatively connected with and/or disposed in association with the top drive and operable to facilitate determination of a sensor measurement of an operational parameter of the top drive;
a loading device detachably connected to a drive shaft of the top drive and operable to impart a load to a motor of the top drive; and
a processing device comprising a processor and a memory storing computer program code, wherein the processing device is communicatively connected with the sensor and the loading device, and wherein the processing device is operable to:
output a first control command to the motor to cause the motor to perform a rotational operation;
output a second control command to the loading device to cause the loading device to impart a load to the motor;
receive the sensor measurement; and
determine operational health of the top drive based on the sensor measurement.

2. The apparatus of claim 1 wherein the rotational operation comprises operating the motor at a constant rotational speed and a constant torque, and wherein the load imparted by the loading device is maintained at a constant level.

3. The apparatus of claim 1 wherein the rotational operation comprises operating the motor at an increasing rotational speed and a constant torque, and wherein the load imparted by the loading device decreases.

4. The apparatus of claim 1 wherein the rotational operation comprises operating the motor at a constant rotational speed and an increasing torque, and wherein the load imparted by the loading device increases.

5. The apparatus of claim 1 wherein:
the sensor measurement is or comprises a temperature measurement and the operational parameter is or comprises temperature of the top drive;
the sensor measurement is or comprises a vibration measurement and the operational parameter is or comprises vibration of the top drive;
the sensor measurement is or comprises a rotational speed measurement and the operational parameter is or comprises rotational speed of the motor or the drive shaft; or
the sensor measurement is or comprises a torque measurement and the operational parameter is or comprises torque outputted by the motor or the drive shaft.

6. The apparatus of claim 1 wherein the loading device is or comprises at least one of:
an electric motor;
an electric generator;
a mechanical brake;
a hydraulic brake;
a rotary table for rotating the drill string; and
a torqueing device for making up and breaking out pipe connections.

7. A method comprising:
commencing operation of a processing device to determine operational health of a top drive for rotating a drill string at a wellsite, wherein the processing device:
outputs a first control command to a motor of the top drive to cause the motor to perform a rotational operation;
outputs a second control command to a loading device coupled to a drive shaft of the top drive to cause the loading device to impart a load to the motor;
receives a sensor measurement indicative of an operational parameter of the top drive; and
determines operational health of the top drive based on the sensor measurement.

8. The method of claim 7 wherein the processing device further:
records the sensor measurement over a period of time;
compares the sensor measurement that is currently received to a sensor measurement that was recorded; and
determines the operational health of the top drive based on the comparison.

9. The method of claim 7 wherein the rotational operation comprises operating the motor at a constant rotational speed and a constant torque, and wherein the load imparted by the loading device is maintained at a constant level.

10. The method of claim 7 wherein the rotational operation comprises operating the motor at an increasing rotational speed and a constant torque, and wherein the load imparted by the loading device decreases.

11. The method of claim 7 wherein the rotational operation comprises operating the motor at a constant rotational speed and an increasing torque, and wherein the load imparted by the loading device increases.

12. The method of claim 7 wherein:
the sensor measurement is or comprises a temperature measurement and the operational parameter is or comprises temperature of the top drive;
the sensor measurement is or comprises a vibration measurement and the operational parameter is or comprises vibration of the top drive;
the sensor measurement is or comprises a rotational speed measurement and the operational parameter is or comprises rotational speed of the motor or the drive shaft; or
the sensor measurement is or comprises a torque measurement and the operational parameter is or comprises torque outputted by the motor or the drive shaft.

13. The method of claim 7 wherein the loading device is or comprises at least one of:
an electric motor;
an electric generator;
a mechanical brake;
a hydraulic brake;
a rotary table for rotating the drill string; and
a torqueing device for making up and breaking out pipe connections.

14. A method comprising:
commencing operation of a processing device to determine operational health of a top drive for rotating a drill string at a wellsite, wherein the processing device:
outputs a first control command to a first motor of the top drive to cause the first motor to perform a rotational operation;
outputs a second control command to a second motor of the top drive to cause the second motor to impart a load to the first motor;
receives a sensor measurement indicative of an operational parameter of the top drive; and
determines operational health of the top drive based on the sensor measurement.

15. The method of claim 14 wherein the processing device further:
records the sensor measurement over a period of time;
compares the sensor measurement that is currently received to a sensor measurement that was recorded; and
determines the operational health of the top drive based on the comparison.

16. The method of claim 14 wherein the rotational operation comprises operating the first motor at a constant rotational speed and a constant torque, and wherein the load imparted by the second motor is maintained at a constant level.

17. The method of claim 14 wherein the rotational operation comprises operating the first motor at an increasing rotational speed and a constant torque, and wherein the load imparted by the second motor decreases.

18. The method of claim 14 wherein the rotational operation comprises operating the first motor at a constant rotational speed and an increasing torque, and wherein the load imparted by the second motor increases.

19. The method of claim 14 wherein:
the rotational operation is a first rotational operation;
the load is a first load;
the sensor measurement is a first sensor measurement;
the operational parameter is a first operational parameter; and
the processing device further:
outputs a third control command to the second motor to cause the second motor to perform a second rotational operation;
outputs a fourth control command to the first motor to cause the first motor to impart a second load to the second motor;
receives a second sensor measurement indicative of a second operational parameter of the top drive; and
determines the operational health of the top drive further based on the second sensor measurement.

20. The method of claim 14 wherein:
the sensor measurement is or comprises a temperature measurement and the operational parameter is or comprises temperature of the top drive;
the sensor measurement is or comprises a vibration measurement and the operational parameter is or comprises vibration of the top drive;
the sensor measurement is or comprises a rotational speed measurement and the operational parameter is or comprises rotational speed of the first motor or second motor; or
the sensor measurement is or comprises a torque measurement and the operational parameter is or comprises torque outputted by the first motor or second motor.
